(19) United States
(12) Patent Application Publication
(10) Pub. No.: US 2012/0241774 A1
(43) Pub. Date: Sep. 27, 2012

(54) DISPLAY MODULE AND MANUFACTURING METHOD THEREOF

(75) Inventors: Shih-Hsiang Chen, Chu-Nan (TW); Chih-Jen Chang, Miao-Li County (TW)

(73) Assignees: CHIMEI INNOLUX CORPORATION, Miao-Li County (TW); INNOCOM TECHNOLOGY(SHENZHEN)CO., LTD., Shenzhen City (CN)

(21) Appl. No.: 13/367,847

(22) Filed: Feb. 7, 2012

(30) Foreign Application Priority Data
Mar. 22, 2011 (TW) 100109774

(51) Int. Cl. H01L 27/15; H01L 33/50

(52) U.S. Cl. 257/88; 438/27; 257/E27.121; 257/E33.058

(57) ABSTRACT

A display module and a manufacturing method thereof are provided. The display module comprises a casing, an optical element and a display panel. The casing has an upper portion. The optical element is disposed in the casing. The display panel comprises a color filter substrate and a thin film transistor substrate. The color filter substrate is located within and toward the casing. The thin film transistor substrate is connected to the color filter substrate and connected to the upper portion of the casing.

This application claims the benefit of Taiwan application Serial No. 100109774, filed Mar. 22, 2011, the subject matter of which is incorporated herein by reference.

### BACKGROUND OF THE INVENTION

1. Field of the Invention

The invention relates in general to a display module and a manufacturing method thereof, and more particularly to a frameless display module and a manufacturing method thereof.

2. Description of the Related Art

Conventional display module comprises a lower casing, an upper casing and a display panel. The display panel is disposed in the lower casing. The upper casing is a heavy frame disposed on the lower casing, and has a hollowed portion, which exposes the display area of the display panel and makes the upper casing become the frame of the display module when viewed in a direction toward the display area. In addition, the upper casing is separated from the display panel by a safety gap to avoid the upper casing colliding and damaging the display panel.

Since the thickness of the entire display module is the sum of the thickness of the lower casing, the distance of the safety gap, and the thickness of the upper casing, the conventional display module is fairly thick and looks heavy and clumsy.

### SUMMARY OF THE INVENTION

The invention is directed to a display module which is thinner in thickness and lighter in weight and a manufacturing method thereof.

According to an aspect of the present invention, a display module is provided. The display module comprises a casing, an optical element and a display panel. The casing has an upper portion. The optical element is disposed in the casing. The display panel comprises a color filter substrate and a thin film transistor substrate. The color filter substrate is located within and toward the casing. The thin film transistor substrate is connected to the color filter substrate and connected to the upper portion of the casing.

According to an alternative aspect of the present invention, a method of manufacturing display module is provided. The manufacturing method comprises the following steps. A casing is provided, wherein the casing has an upper portion and an optical element is disposed in the casing. A display panel is provided, wherein the display panel comprises a color filter substrate and a thin film transistor substrate. The display panel is turned over, so that the color filter substrate of the display panel is located within and toward the casing. The thin film transistor substrate of the display panel is connected to the upper portion of the casing, wherein the color filter substrate of the display panel is located within the casing.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 shows a cross-sectional view of a display panel according to an embodiment of the invention;

FIG. 2 shows a cross-sectional view of a display panel according to another embodiment of the invention;

FIG. 3 shows a top view of the display panel in FIG. 1;

FIG. 4 shows a top view of the thin film transistor substrate in FIG. 1;

FIG. 5 shows a printed circuit board of the display panel in FIG. 1;

FIG. 6 shows a printed circuit board of a display panel according to another implementation; and

FIGS. 7A-7C are manufacturing processes of the display module in FIG. 2.

### DETAILED DESCRIPTION OF THE INVENTION

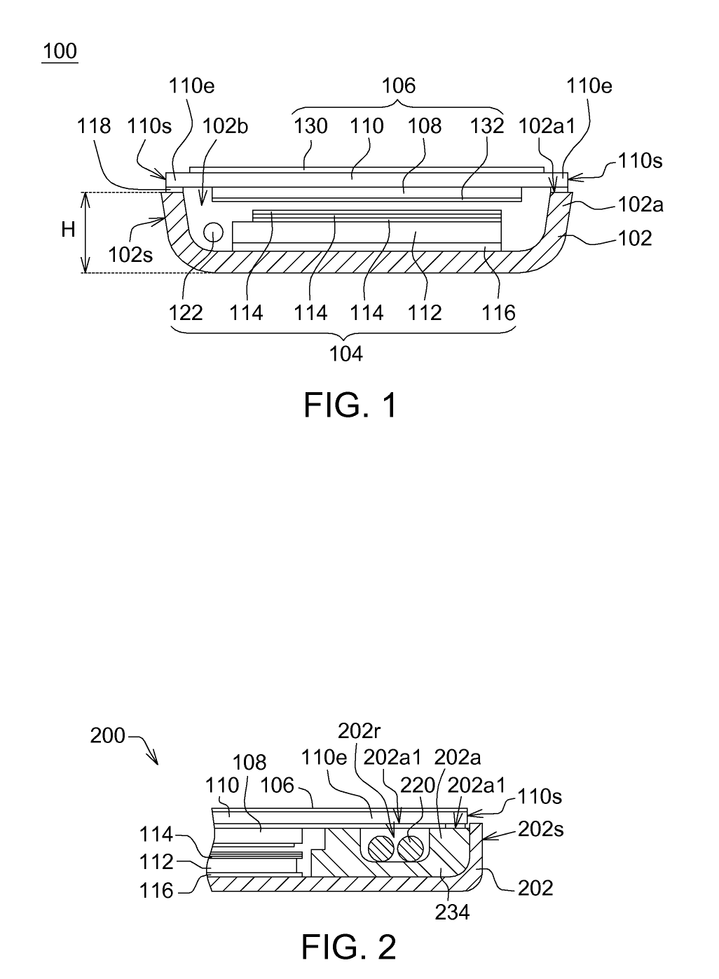

Referring to FIG. 1, a cross-sectional view of a display panel according to an embodiment of the invention is shown. The display module 100, such as a liquid crystal display module or other display module, comprises a casing 102, at least an optical element 104 and a display panel 106.

The casing 102 has an upper portion 102a. The optical element 104 comprises a reflector 116, a light guide plate 112, at least one optical thin film 114 and a light source 122 disposed in the casing 102. The reflector 116, the light guide plate 112, the optical thin film 114 and the light source 122 can form an edge-light type backlight module, but the invention is not limited thereto. The optical thin films 114 can be prism sheets or diffusers. The optical thin films 114 can be the same or different.

The display panel 106 comprises a color filter substrate 108 and a thin film transistor substrate 110. At least a portion of the color filter substrate 108 is located within the casing 102, and the color filter substrate 108 is connected to the thin film transistor substrate 110. The thin film transistor substrate 110 is connected to the upper portion 102a of the casing 102. The thin film transistor substrate 110 can be connected to an end surface 102a1 of the upper portion 102a. The upper portion 102a is the terminal of a side portion of the casing 102. In addition, the display panel 106 further comprises a first polarizing film 130 and a second polarizing film 132, wherein the first polarizing film 130 is disposed on the thin film transistor substrate 110, and the second polarizing film 132 is disposed on the color filter substrate 108.

The display panel 106 of the present embodiment of the invention being connected to the casing 102 can omit the conventional upper casing and makes the display module 100 become a frameless display module, so that the thickness, the cost and the weight are all reduced. As only a portion of the display panel 106 is located within the casing 102, less internal space of the casing 102 is occupied, the thickness H of the casing 102 can be reduced and the material cost can be saved.

The casing 102 has a recess 102b extended to the terminal surface 102a1 of the upper portion 102a. The optical element is disposed in the recess 102b. The thin film transistor substrate 110 of the display panel 106 covers the aperture of the recess 102b and faces toward the exterior of the display module 100, and the color filter substrate 108 of the display panel 106 is located within the recess 102b and faces toward the optical element.

The thin film transistor substrate 110 has a lateral side 110s, and the casing 102 has an outer surface 102s. The lateral side 110s is adjacent to the outer surface 102s. For example, the lateral side 110s and the outer surface 102s are separated by a gap. Or, the lateral side 110s and the outer surface 102s are substantially aligned with each other. The lateral side 110s can be the outmost lateral side of the thin film transistor substrate 110, and the outer surface 102s can be the outmost lateral side of the casing 102.

The display panel and the outer casing can be bonded by way of adhering. For example, one of the display panel 106 and the casing 102 comprises an adhesive 118. The adhesive 118 is disposed on the thin film transistor substrate 110 of the display panel 106 or the upper portion 102a of the casing 102 to bond the thin film transistor substrate 110 of the display panel 106 and the upper portion 102a of the casing 102 together. The position of the adhesive 118 corresponds to the terminal surface 102a1 of the upper portion 102a. In the present embodiment of the invention, the adhesive 118 is disposed on the thin film transistor substrate 110. When the adhesive 118 is disposed on the upper portion 102a of the casing 102, the thin film transistor substrate 110 is disposed on the upper portion 102a through the adhesive 118. The adhesive 118 can be realized by double-sided adhesive or glue. Moreover, the shape of the adhesive 118 can be a closed loop shape or an open loop shape. Or, the adhesive 118 comprises a number of sub-adhesives separately disposed.

In another embodiment, the structure of the casing can be different from that of the casing 102 in FIG. 1.

Referring to FIG. 2, a cross-sectional view of a display panel according to another embodiment of the invention is shown. The display module 200 comprises a display panel 106, a casing 202 and an optical element. The casing 202 has a wiring recess 202r for defining the range of the wire 220. In the present embodiment of the invention, the casing 202 comprises a frame 234 disposed in the casing 202, and the wiring recess 202r is located on the frame 234. In other implementations, the frame 234 in FIG. 2 is a portion of the casing 202. That is, the frame 234 and the casing 202 are integrally formed in one piece. The material composition of the frame 234 comprises at least one of rubber and plastics.

The thin film transistor substrate 110 of the display panel 106 is disposed on the upper portion 202a of the casing 202, such as on the end surface 202a1 of the upper portion 202a. The upper portion 202a is the upper portion of the frame 234. The lateral side 110s of the thin film transistor substrate 110 is adjacent to the outer surface 202s of the casing 202.

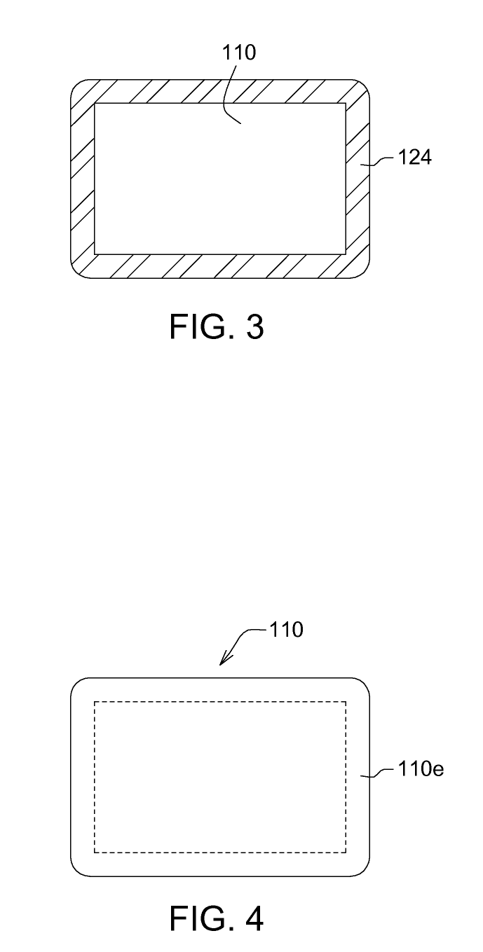

Referring to FIG. 3, a top view of the display panel in FIG. 1 is shown. The display panel 106 comprises a light-shielding layer 124 encircling the thin film transistor substrate 110 for shielding the wire disposed surrounding the thin film transistor substrate 110 to avoid the wire being exposed. The light-shielding layer 124 can be a black matrix (BM). In an implementation, the display panel 106 can omit the light-shielding layer 124.

The thin film transistor substrate has an extension portion corresponding to the upper portion of the casing. As indicated in FIG. 1, the extension portion 110e of the thin film transistor substrate 110 is adjacent to the upper portion 102a of the casing 102. As indicated in FIG. 2, the extension portion 110e of the thin film transistor substrate 110 is adjacent to the upper portion 202a of the casing 202.

In addition, the extension portion of the thin film transistor substrate is located on the periphery of the thin film transistor substrate and becomes at least a side portion of the thin film transistor substrate.

Referring to FIG. 4, a top view of the thin film transistor substrate in FIG. 1 is shown. The extension portion 110e is an encirclement, which encircles the entire peripheral portion of the thin film transistor substrate 110.

In other implementations, the extension portion 110e is an open encirclement, which encircles a part of the peripheral portion of the thin film transistor substrate 110.

In addition, the circuit element of the display panel can be disposed on the extension portion of the thin film transistor substrate.

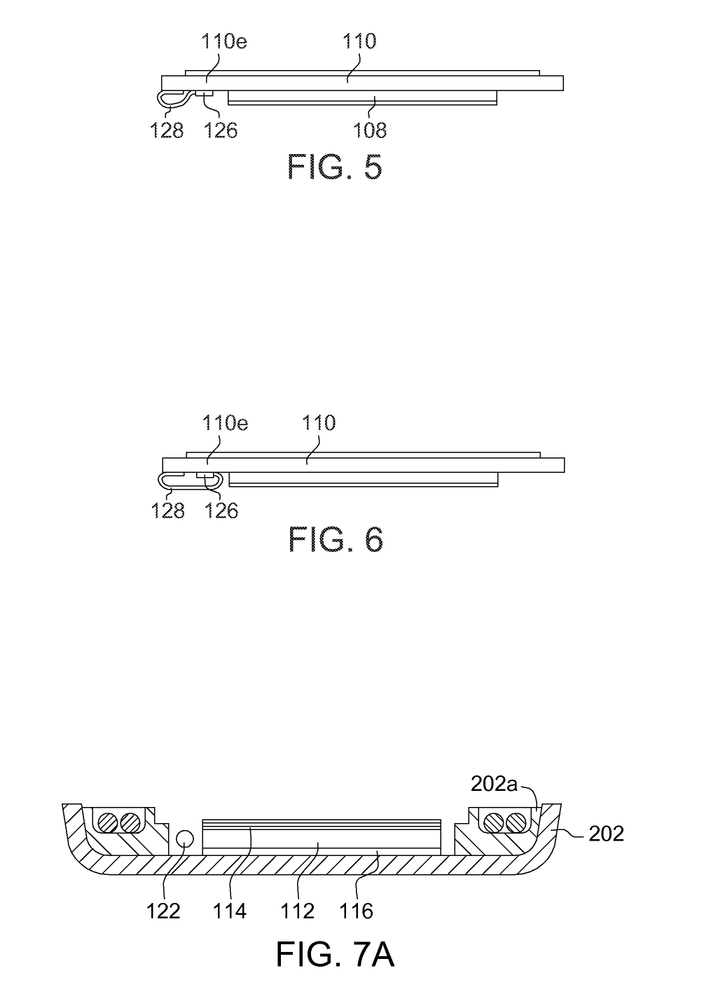

Referring to FIG. 5, a printed circuit board of the display panel in FIG. 1 is shown. The display panel 106 comprises a printed circuit board 126 and a flexible circuit board (FPC) 128. The flexible circuit board 128 connects the printed circuit board 126 and the thin film transistor substrate 110. The printed circuit board 126 is disposed on the thin film transistor substrate 110 through the bent flexible circuit board 128. For example, the printed circuit board 126 is disposed on the extension portion 110e of the thin film transistor substrate 110.

Referring to FIG. 6, a printed circuit board of a display panel according to another implementation is shown. The flexible circuit board 128 encircles the printed circuit board 126 for at least one circle and is disposed on the extension portion 110e of the thin film transistor substrate 110. In other implementations, the printed circuit board 126 can also be disposed on the flexible circuit board 128 through the bending of the flexible circuit board 128. In addition, after the flexible circuit board 128 is bent, the printed circuit board 126 can be bonded on flexible circuit board 128 or the thin film transistor substrate 110 by way of adhering.

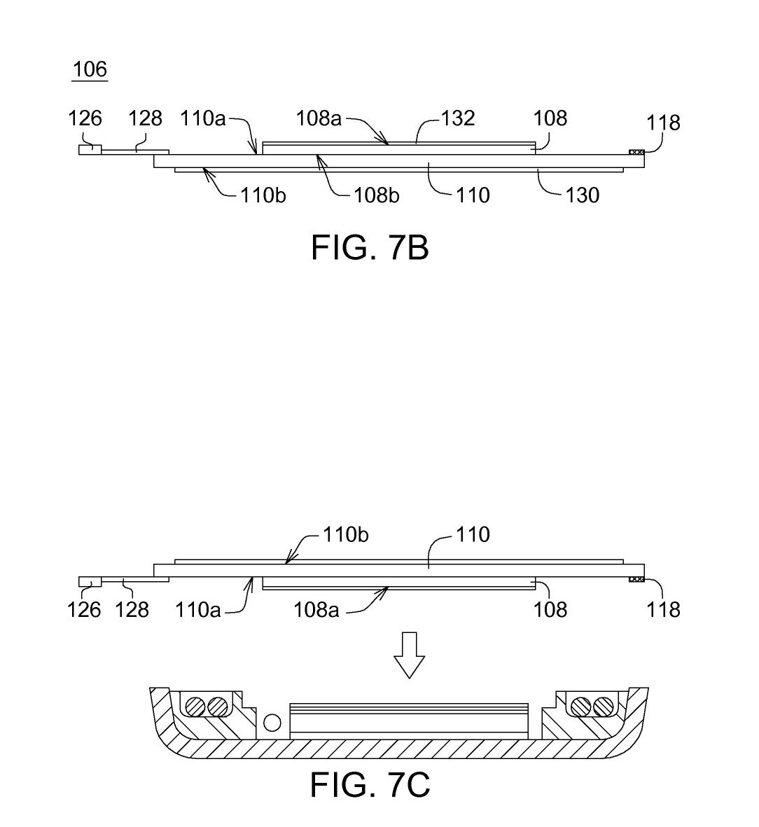

The manufacturing method of the display module of an embodiment of the invention is disclosed below with the exemplification of the display module 200 in FIG. 2. Referring to FIGS. 7A-7C, manufacturing processes of the display module in FIG. 2 are shown.

As indicated in FIG. 7A, a casing 202 is provided, wherein the casing 202 has an upper portion 202a and an optical element, which includes a reflector 116, a light guide plate 112, at least an optical thin film 114 and a light source 122).

As indicated in FIG. 7B, a display panel 106 is provided. The display panel 106 comprises a color filter substrate 108 and a thin film transistor substrate 110. In the conventional production line, the color filter substrate 108 of the display panel 106 normally faces upwards. Moreover, the display panel 106 comprises a printed circuit board 126, a flexible circuit board 128 and an adhesive 118. The adhesive 118 is disposed on the thin film transistor substrate 110. In other implementations, the adhesive 118 can also be disposed on the upper portion 202a of the casing 202, such as on the end surface 202a1 of the upper portion 202a.

The color filter substrate 108 has a first side 108a and a second side 108b opposite to the first side 108a. The thin film transistor substrate 110 has a first side 110a and a second side 110b opposite to the first side 110a. The transistor structure (not illustrated) of the thin film transistor substrate 110 is adjacent to the first side 110a. The color filter substrate 108 is connected to the first side 110a of the thin film transistor substrate 110 by the second side 108b. The flexible circuit board 128 is disposed on the first side 110a of the thin film transistor substrate 110.

Prior to the step of providing the display panel 106, the manufacturing method of the display module 200 further comprises a step of manufacturing the display panel 106, in which the light-shielding layer 124 in FIG. 3 can be manufactured. The step of manufacturing the display panel 106 comprises: providing the thin film transistor substrate 110. Then, the light-shielding layer 124 in FIG. 3 is formed on the thin film transistor substrate 110, such as on the second side 110b. The light-shielding layer 124 encircles the thin film transistor substrate 110 for shielding the thin film transistor substrate 110 to avoid the wire being exposed. Then, the color filter substrate 108 is adhered on the thin film transistor substrate 110. Then, the first polarizing film 130 is adhered on the second side 110b of the thin film transistor substrate 110. Then, the second polarizing film 132 is adhered on the first side 108a of the color filter substrate 108.

As indicated in FIG. 7C, the display panel 106 is turned over, so that the color filter substrate 108 of the display panel 106 faces toward the casing 202. For example, the first side 108a faces toward the casing 202. The display panel 106 is turned over for an angle about 180 degrees. However, the angle is not for limiting the present embodiment of the invention. In other implementations, the display panel 106 can be turned over for another angle if the equipment permits.

Then, the thin film transistor substrate 110 of the display panel 106 is disposed on the upper portion 202a of the casing 202, wherein the color filter substrate 108 of the display panel 106 is located within the casing 202 as indicated in FIG. 2. Furthermore, the thin film transistor substrate of the display panel 110 is bonded to the end surface 202a1 of the upper portion 202a of the casing 202 through the adhesive 118.

Prior to the step of connecting the thin film transistor substrate of the display panel on the upper portion of the casing, the manufacturing method of the display module 200 further comprises: bending the flexible circuit board 128. The printed circuit board 126 can be disposed on one or at least one of the thin film transistor substrate 110, the first polarizing film 130, the second polarizing film 132 and the color filter substrate 108 through the bending of the flexible circuit board 128. For example, the printed circuit board 126 is disposed on the thin film transistor substrate 110 through the bending of the flexible circuit board 128, such as on the first side 110a of the thin film transistor substrate 110. In other implementations, the printed circuit board 126 is disposed on the color filter substrate 108 through the bending of the flexible circuit board 128. In addition, the flexible circuit board 128 may or may not encircle the printed circuit board. As indicated in FIG. 5, the flexible circuit board 128 does not encircle the printed circuit board 126. As indicated in FIG. 6, the flexible circuit board 128 encircles the printed circuit board 126 for at least one circle.

The display module and the manufacturing method thereof disclosed in the above embodiments of the invention have many features exemplified below:

1). The display module omits the conventional upper casing, and becomes a frameless design which reduces the thickness, the cost and the weight.

2). Since only a portion of the display panel is located within the casing, so less internal space of the casing is occupied, the thickness of the casing can be reduced and the thickness of the entire display module can be reduced accordingly.

3). The light-shielding layer shields the wire surrounding the thin film transistor substrate to avoid the wire being exposed.

4). The printed circuit board connected to the thin film transistor substrate and the flexible circuit board can be bent and disposed on the thin film transistor substrate.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A display module, comprising:
a casing having an upper portion;
an optical element disposed in the casing, and
a display panel, comprising:
a thin film transistor substrate connected to the upper portion of the casing; and
a color filter substrate connected to the thin film transistor substrate and located within and toward the casing.

2. The display module according to claim 1, wherein the thin film transistor substrate has a lateral side, the casing has an outer surface, and the lateral side is adjacent to the outer surface.

3. The display module according to claim 1, wherein the casing has a recess within which the optical element is disposed, and the thin film transistor substrate covers the recess.

4. The display module according to claim 1, wherein the display panel comprises:
a light-shielding layer formed on a periphery of the thin film transistor substrate.

5. The display module according to claim 1, wherein the display panel further comprises:
a printed circuit board; and
a flexible circuit board connecting the printed circuit board and the thin film transistor substrate;
wherein, the printed circuit board is disposed on the thin film transistor substrate through the bent flexible circuit board.

6. The display module according to claim 5, wherein the flexible circuit board encircles the printed circuit board for at least one circle.

7. The display module according to claim 1 further comprising:
an adhesive disposed between the thin film transistor substrate of the display panel and the upper portion of the casing for bonding the thin film transistor substrate of the display panel and the upper portion of the casing.

8. The display module according to claim 1, wherein the thin film transistor substrate has an extension portion corresponding to the upper portion of the casing.

9. A method of manufacturing display module, comprising:
providing a casing, wherein the casing has an upper portion, and an optical element is disposed in the casing;
providing a display panel, wherein the display panel comprises a color filter substrate and a thin film transistor substrate;
turning the display panel over, so that the color filter substrate of the display panel faces toward the casing; and
connecting the thin film transistor substrate of the display panel to the upper portion of the casing, wherein the color filter substrate of the display panel is located within the casing.

10. The manufacturing method according to claim 9, wherein prior to the step of providing the display panel, the method further comprises:
manufacturing the display panel, comprising:
providing a thin film transistor substrate; and
forming a light-shielding layer on the thin film transistor substrate,
wherein the light-shielding layer is located on a periphery of the thin film transistor substrate.

11. The manufacturing method according to claim 9, wherein the display panel further comprises a printed circuit board and a flexible circuit board, the flexible circuit board connects the printed circuit board and the thin film transistor substrate, and the manufacturing method further comprises:
bending the flexible circuit board so that the printed circuit board is disposed on the thin film transistor substrate through the bent flexible circuit board.

12. The manufacturing method according to claim 11, wherein in the step of bending the flexible circuit board, the flexible circuit board encircles the printed circuit board for at least one circle.

13. The manufacturing method according to claim 9, wherein one of the display panel and the casing comprises an adhesive;
in the step of connecting the thin film transistor substrate of the display panel on the upper portion of the casing, the thin film transistor substrate of the display panel is connected to the upper portion of the casing through the adhesive.
